(19) United States
(12) Patent Application Publication
(10) Pub. No.: US 2026/0282465 A1
(43) Pub. Date: Sep. 17, 2026

(54) SEMICONDUCTOR DEVICE AND MANUFACTURING METHOD THEREOF

(71) Applicant: Kioxia Corporation, Tokyo (JP)

(72) Inventors: Shuntaro KIMURA, Yokkaichi Mie (JP); Ryota ASADA, Kuwana Mie (JP); Yasunori OKAYAMA, Yokkaichi Mie (JP); Hiroyuki KUTSUKAKE, Kuwana Mie (JP); Satoshi MATSUDA, Yokkaichi Mie (JP); Tsuyoshi HIRAYU, Yokkaichi Mie (JP); Mamoru WATANABE, Yokkaichi Mie (JP); Keisuke NAKATSUKA, Kobe Hyogo (JP); Susumu HASHIMOTO, Kuwana Mie (JP); Mitsuhiko NODA, Kuwana Mie (JP); Junya SAKANO, Yokohama Kanagawa (JP); Takeshi SHIMANE, Matsudo Chiba (JP); Takashi IZUMIDA, Kamakura Kanagawa (JP); Taishi HAGA, Yokohama Kanagawa (JP)

(73) Assignee: Kioxia Corporation, Tokyo (JP)

(21) Appl. No.: 19/321,533

(22) Filed: Sep. 8, 2025

(30) Foreign Application Priority Data
Mar. 14, 2025 (JP) 2025-041831

(51) Int. Cl. H10D 62/10; H01L 23/48; H01L 25/18; H10B 43/35; H10B 80/00; H10D 80/30; H10D 84/01; H10D 84/85

(52) U.S. Cl. CPC H10D 62/112; H10B 43/35; H10D 84/0188; H10D 84/859; H10W 20/20; H10B 80/00; H10D 80/30; H10W 90/00; H10W 90/26; H10W 90/297

(57) ABSTRACT

A semiconductor device includes a first structure and a second structure. First semiconductor elements are arranged in the first structure. The second structure is stacked on the first structure. The second structure includes a substrate including a first surface and a second surface opposing to each other, a first well region of a first conductivity type arranged on the side of the first surface of the substrate, a second well region of a second conductivity type arranged on the side of the first surface to be adjacent to the first well region, and a first impurity layer of the first conductivity type arranged at least on the side of the second surface of the first well region and having a higher impurity concentration than that of the first well region. A first conductor is located between the first structure and the second structure and is electrically separated from the substrate.

### CROSS REFERENCE TO RELATED APPLICATIONS

This application is based upon and claims the benefit of priority from the prior Japanese Patent Application No. 2025-041831, filed on Mar. 14, 2025, the entire contents of which are incorporated herein by reference.

### FIELD

The embodiments of the present invention relate to a semiconductor device and a manufacturing method thereof.

### BACKGROUND

Some semiconductor storage devices such as a NAND flash memory have a stacked structure including an array chip where a memory cell array is arranged, and a CMOS (Complementary Metal Oxide Semiconductor) chip where a CMOS circuit is arranged.

### BRIEF DESCRIPTION OF THE DRAWINGS

FIG. 1 is a block diagram illustrating a configuration example of a storage device according to a first embodiment;

FIG. 2 is a block diagram illustrating a configuration example of the storage device according to the first embodiment;

FIG. 3 is a perspective view illustrating a configuration example of the storage device according to the first embodiment;

FIG. 4 is a conceptual diagram illustrating a configuration example of the storage device according to the first embodiment;

FIG. 5 is a sectional view illustrating a configuration example of the storage device according to the first embodiment;

FIG. 6 is a sectional view illustrating a configuration example of a memory pillar of the storage device according to the first embodiment;

FIG. 7 is a sectional view illustrating a configuration example of a part of a first structure and a second structure according to the first embodiment;

FIG. 8 is a sectional view illustrating one example of a manufacturing method of the second structure of the storage device according to the first embodiment;

FIG. 9 is a sectional view illustrating one example of the manufacturing method of the second structure, in continuation from FIG. 8;

FIG. 10 is a sectional view illustrating one example of the manufacturing method of the second structure, in continuation from FIG. 9;

FIG. 11 is a sectional view illustrating one example of the manufacturing method of the second structure, in continuation from FIG. 10;

FIG. 12 is a sectional view illustrating one example of the manufacturing method of the second structure, in continuation from FIG. 11;

FIG. 13 is a sectional view illustrating one example of the manufacturing method of the second structure, in continuation from FIG. 12;

FIG. 14 is a sectional view illustrating one example of the manufacturing method of the second structure, in continuation from FIG. 13;

FIG. 15 is a sectional view illustrating one example of the manufacturing method of the second structure, in continuation from FIG. 14;

FIG. 16 is a sectional view illustrating one example of a manufacturing method of a second structure of a storage device according to a second embodiment;

FIG. 17 is a sectional view illustrating one example of the manufacturing method of the second structure of the storage device according to the second embodiment;

FIG. 18 is a sectional view illustrating one example of the manufacturing method of the second structure of the storage device according to the second embodiment;

FIG. 19 is a sectional view illustrating a configuration example of a second structure of a storage device according to a fourth embodiment;

FIG. 20 is a sectional view illustrating a configuration example of a second structure of a storage device according to a fifth embodiment;

FIG. 21 is a sectional view illustrating a configuration example of a storage device according to a sixth embodiment; and

FIG. 22 is a table showing a relation between the impurity concentration of an impurity layer where an inverted layer is not formed and the distance from each of conductors to an associated one of p-well regions.

### DETAILED DESCRIPTION

In general, a semiconductor device according to the present embodiment includes a first structure and a second structure. A plurality of first semiconductor elements are arranged in the first structure. The second structure is stacked on the first structure. The second structure includes a substrate including a first surface and a second surface on the opposite side to the first surface, a first well region of a first conductivity type arranged on the side of the first surface of the substrate, a second well region of a second conductivity type arranged on the side of the first surface of the substrate to be adjacent to the first well region, and a first impurity layer of the first conductivity type arranged at least on the side of the second surface of the first well region and having a higher impurity concentration than that of the first well region. A first conductor is located between the first structure and the second structure and is electrically separated from the substrate. Hereinafter, devices of the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

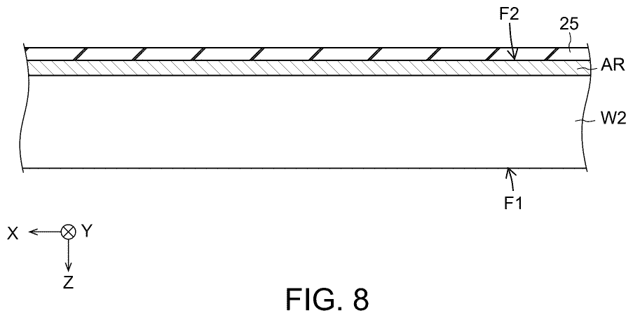

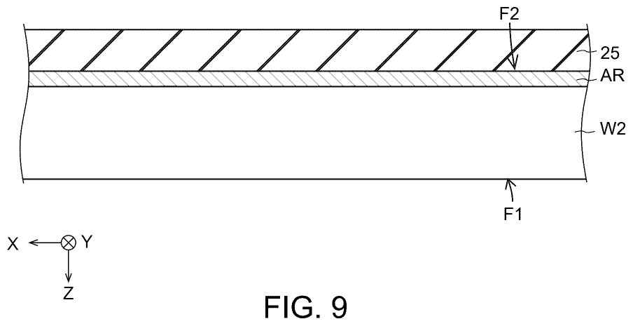

As used in the present specification and the claims, when a first element is “connected” to another second element, the first element can be connected to the second element directly, or via an element that becomes conductive either constantly or selectively. While it is assumed that a +Z direction is an upward direction and a-Z direction is a downward direction in the present specification and the drawings, it is sometimes assumed in FIGS. 8 and 9 that the-Z direction is conversely the upward direction and the +Z direction is the downward direction.

### First Embodiment

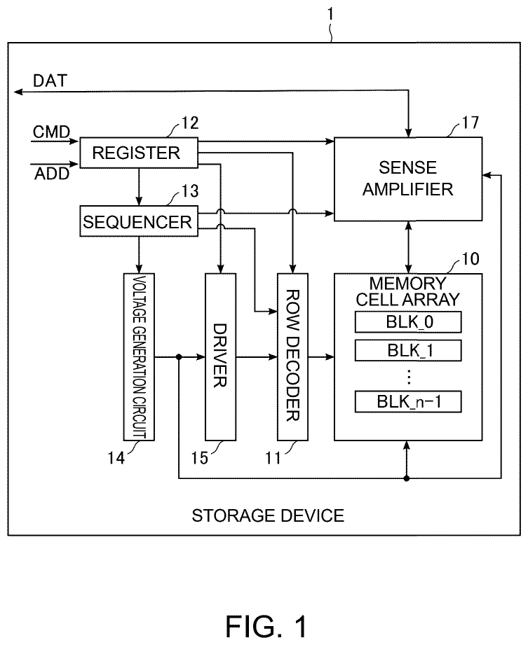

FIG. 1 is a block diagram illustrating a configuration example of a storage device according to a first embodiment. A storage device 1 as one example of a semiconductor device is a device that stores therein data using memory cells. The storage device 1 is, for example, a NAND flash memory. The storage device 1 is controlled by an external memory controller. The storage device 1 operates, for example, based on a command CMD and address information ADD received from the memory controller. The storage device 1 receives data DAT to be written, and outputs data stored in the storage device 1.

The storage device 1 includes constituent elements such as a memory cell array 10, row decoders 11, a register 12, a sequencer 13, a voltage generation circuit 14, a driver 15, and a sense amplifier 17.

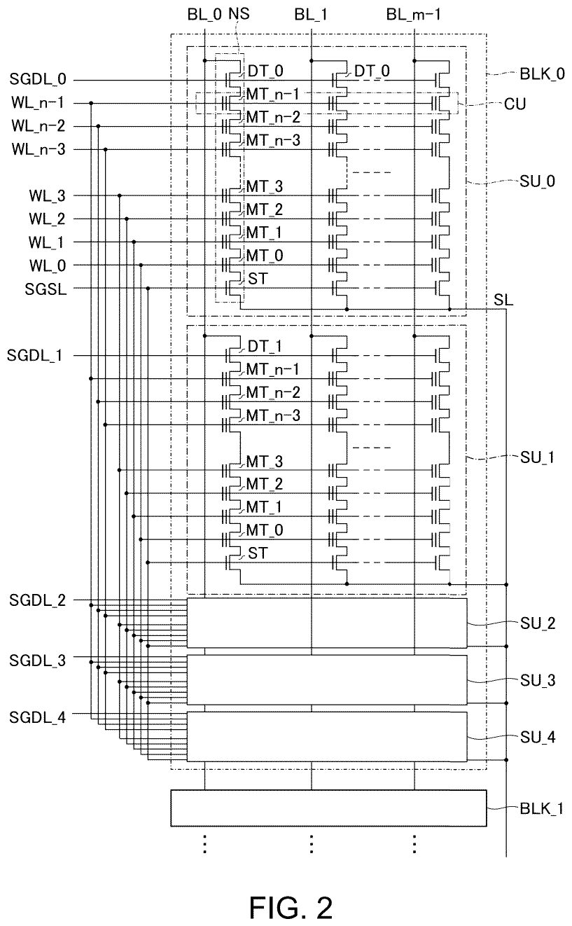

The memory cell array 10 is a set of arrayed memory cells. The memory cell array 10 includes a plurality of memory blocks (blocks) BLK. Each block BLK includes a plurality of memory cell transistors MT (see FIG. 2). A region where the memory cell array 10 is arranged also includes lines such as word lines WL (see FIG. 2) and bit lines BL (see FIG. 2).

The row decoders 11 are circuits for selecting a block BLK. The row decoders 11 transfer a voltage supplied from the driver 15 to one block BLK selected based on a block address received by the row decoders 11 from the register 12.

The register 12 is a circuit that retains a command CMD and address information ADD received by the storage device 1. The command CMD instructs various operations including a data read operation, a data write operation, and a data erase operation to the sequencer 13. The address information ADD designates an access target in the memory cell array 10.

The sequencer 13 is a circuit that controls the entire operation of the storage device 1. The sequencer 13 controls the row decoders 11, the driver 15, and the sense amplifier 17 on the basis of the command CMD received by the sequencer 13 to perform various operations including a data read operation, a data write operation, and a data erase operation.

The voltage generation circuit 14 is a circuit that generates different levels of voltages. The voltage generation circuit 14 receives a power voltage from outside the storage device 1 and generates voltages from the power voltage. The voltage generation circuit 14 supplies the generated voltages to constituent elements such as the memory cell array 10, the driver 15, and the sense amplifier 17.

The driver 15 is a circuit that applies various voltages required for the operation of the storage device 1 to some constituent elements. The driver 15 receives plural voltages from the voltage generation circuit 14 and supplies selected ones of the voltages to one or more row decoders 11.

The sense amplifier 17 is a circuit that outputs a signal based on data stored in the memory cell array 10. The sense amplifier 17 senses the state of a relevant memory cell transistor MT (hereinafter, also simply “memory cell”) and generates read data on the basis of the sensed state. The sense amplifier 17 applies a voltage based on data to be written, to a bit line BL.

FIG. 2 is a block diagram illustrating a configuration example of the storage device according to the first embodiment. A plurality of the blocks BLK, for example, all the blocks BLK include constituent elements and connections illustrated in FIG. 2.

One block BLK includes a plurality of string units SU. FIG. 2 illustrates an example of five string units SU_0 to SU_4.

As illustrated in FIG. 2, each of m bit lines BL_0 to BL_m-1 is connected to one NAND string NS in each of the string units SU_0 to SU_4 in each block BLK. In this example, m is a positive integer.

Each NAND string NS includes one selection gate transistor ST, n memory cell transistors MT (MT_0 to MT_n-1), and one selection gate transistor DT (DT_0, DT_1, DT_2, DT_3, or DT_4). In this example, n is a positive integer. Each of the memory cell transistors MT is an element that functions as a memory cell and stores therein data in a nonvolatile manner. Each memory cell transistor MT includes a control gate electrode or a gate electrode (a word line WL) and a charge accumulation film insulated from the peripheral part, and stores therein data in a nonvolatile manner on the basis of charges in the charge accumulation film. Data is written to each of the memory cell transistors MT by injection of electrons into the charge accumulation film.

The selection gate transistor ST, the memory cell transistors MT_0 to MT_n-1, and the selection gate transistor DT are connected in series in this order between a source line SL and one bit line BL.

A plurality of NAND strings NS respectively connected to a plurality of different bit lines BL constitute one string unit SU. In each string unit SU, the control gate electrodes of the memory cell transistors MT_0 to MT_n-1 are connected to word lines WL_0 to WL_n-1, respectively. A set of memory cell transistors MT sharing a word line WL in one string unit SU is referred to as “cell unit CU”.

The selection gate transistors DT_0 to DT_4 belong to the string units SU_0 to SU_4, respectively. In FIG. 2, illustrations of the selection gate transistors DT_2, DT_3, and DT_4 are omitted. The gates of the selection gate transistors DT_0 in the NAND strings NS in the string unit SU_0 are connected to a selection gate line SGDL_0. Similarly, the gates of the selection gate transistors DT_1, DT_2, DT_3, and DT_4 in the associated NAND strings NS in the string units SU_1, SU_2, SU_3, and SU_4 are connected to selection gate lines SGDL_1, SGDL_2, SGDL_3, and SGDL_4, respectively.

The gates of the selection gate transistors ST are connected to a selection gate line SGSL.

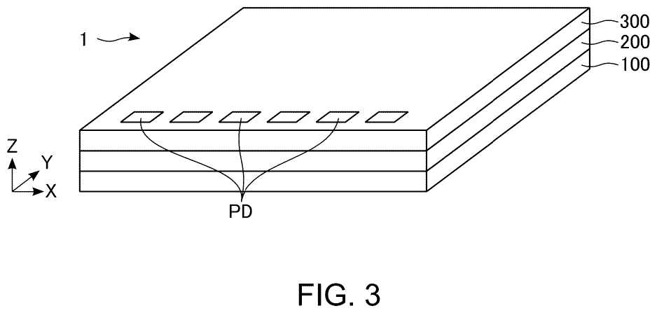

FIG. 3 is a perspective view illustrating a configuration example of the storage device according to the first embodiment. The storage device 1 includes a first structure 100, a second structure 200, and a third structure 300. The first structure 100, the second structure 200, and the third structure 300 spread along an XY plane and are stacked in the Z direction. The second structure 200 is located on a surface (the upper surface) of the first structure 100 on a side in the Z direction. The third structure 300 is located on the upper surface of the second structure 200.

Each of the first structure 100, the second structure 200, and the third structure 300 includes a plurality of semiconductors, a plurality of various conductors, and a plurality of insulators formed on a substrate using the substrate. Each of the first structure 100, the second structure 200, and the third structure 300 includes a plurality of elements and lines realized by semiconductors, conductors, and insulators. Each of the first structure 100, the second structure 200, and the third structure 300 includes an electrical circuit including elements and lines. The elements and lines in the first structure 100, the elements and lines in the second structure 200, and the elements and lines in the third structure 300 are electrically connected to each other. Each of the first structure 100, the second structure 200, and the third structure 300 is formed as an individual semiconductor chip. The first structure 100, the second structure 200, and the third structure 300 are bonded to each other to be a semiconductor chip of one storage device 1.

A set of the first structure 100 and the second structure 200 includes the row decoders 11, the register 12, the sequencer 13, the voltage generation circuit 14, the driver 15, and the sense amplifier 17. The first structure 100 includes any constituent elements among the row decoders 11, the register 12, the sequencer 13, the voltage generation circuit 14, the driver 15, and the sense amplifier 17. The second structure 200 includes any constituent elements among the row decoders 11, the register 12, the sequencer 13, the voltage generation circuit 14, the driver 15, and the sense amplifier 17. For example, the first structure 100 includes semiconductor elements constituting the row decoders 11, the register 12, the sequencer 13, the voltage generation circuit 14, and the driver 15. The second structure 200 includes semiconductor elements constituting the sense amplifier 17. Each of the row decoders 11, the register 12, the sequencer 13, the voltage generation circuit 14, the driver 15, and the sense amplifier 17 is constituted of a CMOS circuit including a p-type MOSFET (Metal Oxide Semiconductor Field Effect Transistor) and an n-type MOSFET. Each of the first structure 100 and the second structure 200 is, for example, a CMOS chip including such a CMOS circuit.

The third structure 300 is, for example, an array chip including the memory cell array 10 and a plurality of external connection terminals PD. The external connection terminals PD are exposed on the upper surface of the third structure 300.

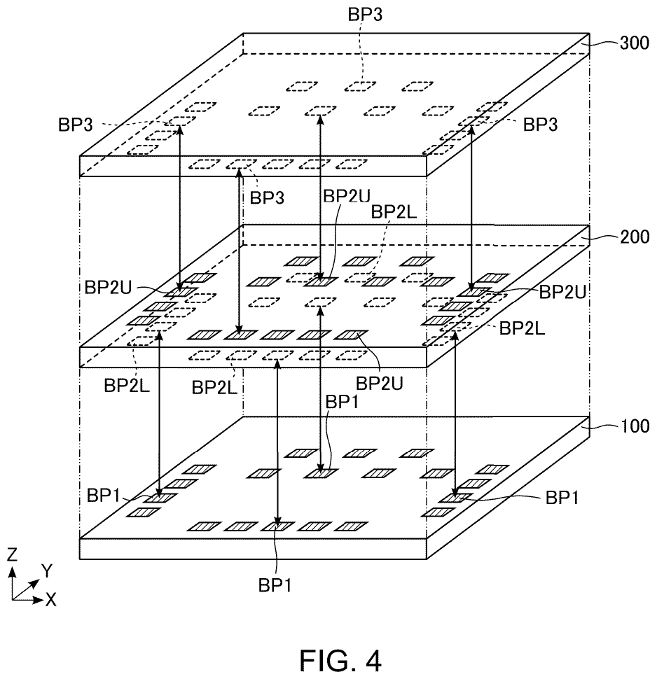

FIG. 4 is a conceptual diagram illustrating a configuration example of the storage device according to the first embodiment. FIG. 4 illustrates the structure illustrated in FIG. 3 in an exploded manner.

The first structure 100 includes a plurality of conductive joint terminals BP1. The joint terminals BP1 are exposed on the upper surface of the first structure 100. The joint terminals BP1 are connected to the elements in the first structure 100.

The second structure 200 includes a plurality of conductive joint terminals BP2L and a plurality of conductive joint terminals BP2U. The joint terminals BP2L are exposed on a surface (the lower surface) of the second structure 200 on a side in the-Z direction. The joint terminals BP2L are connected to the elements in the second structure 200. The joint terminals BP2L have the same layout as that of the joint terminals BP1 of the first structure 100. The joint terminals BP2L are arrayed in such a manner that each of the joint terminals BP2L is in contact with one of the joint terminals BP1 of the first structure 100 corresponding to this joint terminal BP2L when the first structure 100 and the second structure 200 are joined to each other. A certain joint terminal BP2L and one of the joint terminals BP1 of the first structure 100 corresponding to the certain joint terminal BP2L are elements functioning as the same node in a circuit.

The joint terminals BP2U are exposed on the upper surface of the second structure 200. The joint terminals BP2U are connected to the elements in the second structure 200.

The third structure 300 includes a plurality of conductive joint terminals BP3. The joint terminals BP3 are exposed on the lower surface of the third structure 300. The joint terminals BP3 are connected to the elements in the third structure 300. The joint terminals BP3 have the same layout as that of the joint terminals BP2U of the second structure 200. The joint terminals BP3 are arrayed in such a manner that each of the joint terminals BP3 is in contact with one of the joint terminals BP2U of the second structure 200 corresponding to this joint terminal BP3 when the second structure 200 and the third structure 300 are joined to each other. A certain joint terminal BP3 and one of the joint terminals BP2U of the second structure 200 corresponding to the certain joint terminal BP3 are elements functioning as the same node in a circuit.

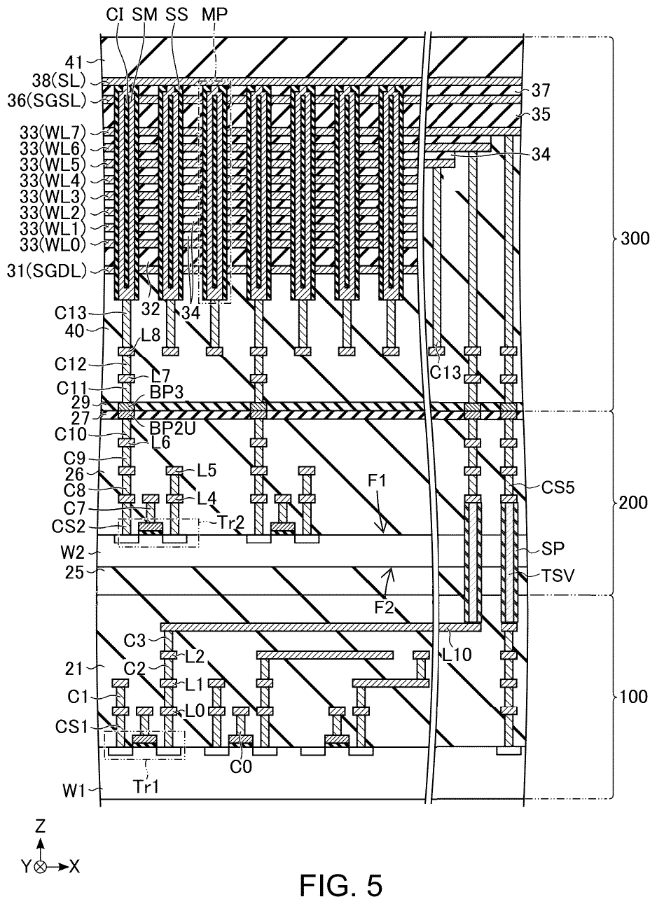

The connection among the first to third structures 100 to 300 is realized by through-electrodes TSV without using the joint terminals in Some Cases.
FIG. 5 is a sectional view illustrating a configuration example of the storage device according to the first embodiment. The first structure 100 is bonded to the second structure 200 on the side of a second surface F2 of a substrate W2 to be stacked thereon. The third structure 300 is bonded to the second structure 200 on the side of a first surface F1 of the substrate W2 to be stacked thereon.

The first structure 100 further includes a substrate W1, transistors Tr1, contacts CS1, C0, C1, C2, and C3, conductors L0, L1, L2, and L10, and an insulator 21. In the following descriptions, conductors also include semiconductors having a conductive property due to inclusion of a metallic material or impurities. In one example, the substrate W1 includes silicon. In one example, each of the contacts CS1, C0, C1, C2, and C3 and the conductors L0, L1, L2, and L10 includes copper or tungsten. In one example, the insulator 21 includes silicon oxide.

The transistors Tr1 are positioned in a region of an upper part of the substrate W1 and near the upper surface. Each of the transistors Tr1 includes a gate insulator on the upper surface of the substrate W1, a gate electrode on the upper surface of the gate insulator, and a region (source/drain region) of one pair of a source and a drain sandwiching a region below the gate electrode. Each of the transistors Tr1 is electrically connected to any of conductors (for example, word lines WL) 31, 33, and 36 via a conductor (for example, a line) L10 and a through-electrode TSV. Accordingly, the transistors Tr1 of the first structure 100 can constitute the driver (drive circuit) 15 that controls the voltages of the conductors 31, 33, and 36.

Each contact C0 is in contact on the lower surface with the upper surface of the gate electrode of one transistor Tr1. Each contact CS1 is in contact on the lower surface with one source/drain region.

Each conductor L0 is in contact on the lower surface with one contact C0 or CS1. Each contact C1 is in contact on the lower surface with the upper surface of one conductor L0.

Each conductor L1 is in contact on the lower surface with the upper surface of one contact C1. Each contact C2 is in contact on the lower surface with the upper surface of one conductor L1.

Each conductor L2 is in contact on the lower surface with the upper surface of one contact C2. Each contact C3 is in contact on the lower surface with the upper surface of one conductor L2.

Each conductor L10 is in contact on the lower surface with the upper surface of one contact C3. In one example, the conductors L10 include copper (Cu), aluminum (Al), and (or) tungsten (W). A through-electrode TSV is in contact on the lower surface with the upper surface of one conductor L10. The conductors L10 are electrically connected to the voltage generation circuit 14 in FIG. 1 and receive a high positive voltage. The conductors L10 are arranged on the surface of the substrate W1 with the insulator 21 interposed therebetween. The conductors L10 are each electrically connected to a transistor Tr1 of the first structure 100 via contacts C1 to C3 and the like. The conductors L10 are each electrically connected to a conductor 31, 33, or 36 of the third structure 300 via a through-electrode TSV and the like.

A set of the transistor Tr1, the contacts CS1, C0, C1, C2, and C3, and the conductors L0, L1, L2, and L10 realizes a circuit included in the first structure 100. Therefore, the first structure 100 has any shapes and arrangement of the transistors Tr1, the contacts CS1, C0, C1, C2, and C3, and the conductors L0, L1, L2, and L10 realizing circuits included in the first structure 100.

The insulator 21 is arranged from the level of the upper surface of the substrate W1 to above the upper surfaces of the conductors L10. The insulator 21 fills a region where the constituent elements are not arranged in the first structure 100, that is, a region where the transistors Tr1, the contacts CS1, C0, C1, C2, and C3, and the conductors L0, L1, L2, and L10 are not arranged.

In the example illustrated in FIG. 5, the connection between the first structure 100 and the second structure 200 is realized using the through-electrodes TSV. Of course, the joint terminals BP1 may be provided in the insulator 21 to be respectively connected to the joint terminals BP2L of the second structure 200 as described with reference to FIG. 4. In this case, the insulator 21 fills a region where the through-electrodes TSV or the joint terminals BP1 are not arranged.

The second structure 200 further includes the substrate W2, transistors Tr2, contacts CS2, CS5, C7, C8, C9, and C10, conductors L4, L5, and L6, and insulators 25, 26, and 27. The substrate W2 includes the first surface F1, and the second surface F2 on the opposite side to the first surface F1. In one example, the substrate W2 includes silicon. The thickness of the substrate W2 is, for example, 0.2 to 2 μm (micrometer). In one example, each of the contacts CS2, CS5, C7, C8, C9, and C10, and the conductors L4, L5, and L6 includes copper or tungsten. In one example, each of the insulators 25, 26, and 27 includes silicon oxide. The upper surface of the second structure 200 is on the side of the first surface F1 of the substrate W2 and the lower surface of the second structure 200 is on the side of the second surface F2 of the substrate W2.

As described above, the connection between the first structure 100 and the second structure 200 is realized using the through-electrodes TSV in the example illustrated in FIG. 5. Of course, the joint terminals BP2L may be provided in the insulator 25 to be respectively connected to the joint terminals BP1 of the first structure 100 as described with reference to FIG. 4. In this case, the insulator 25 fills a region where the through-electrodes TSV or the joint terminals BP2L are not arranged.

The insulator 25 is arranged from the level of the upper surface of the insulator 21 of the first structure 100 to the second surface F2. The insulator 25 is arranged between an impurity layer AR and the conductors L10. The insulator 25 fills a region where the through-electrodes TSV are not arranged in a region above the insulator 21 of the first structure 100.

The substrate W2 is positioned on the upper surface of the insulator 25. The through-electrodes TSV penetrate through the substrate W2 from the first surface F1 of the substrate W2 to the second surface F2 thereof. Each of the through-electrodes TSV is in contact on the upper surface with the lower surface of a conductor L4. Each of the through-electrodes TSV is in contact on the lower surface with the upper surface of a conductor L10 in the first structure 100. Insulators SP penetrate through the substrate W2 from the upper surface of the substrate W2 to the lower surface thereof. Each insulator SP covers the side surface of one through-electrode TSV. Each of the through-electrodes TSV is electrically separated from the substrate W2 by the insulator SP.

The transistors Tr2 are arranged on the side of the first surface F1 of the substrate W2. Each of the transistors Tr2 includes a gate insulator on the upper surface of the substrate W2, a gate electrode on the upper surface of the gate insulator, and a region (source/drain region) of one pair of a source and a drain sandwiching a region below the gate electrode. Each of the transistors Tr2 is electrically connected to any of semiconductor layers SM of memory pillars MP. Accordingly, the transistors Tr2 of the second structure 200 constitute the sense amplifier 17 that detects data stored in memory cells via the associated semiconductor layers SM of the memory pillars MP.

Each contact C7 is in contact on the lower surface with the upper surface of the gate electrode of one transistor Tr2. Each contact CS2 is in contact on the lower surface with one source/drain region. Each contact CS5 is in contact on the lower surface with the upper surface of one conductor L4.

Each conductor L4 is in contact on the lower surface with the upper surface of one contact C7 or CS2, or one through-electrode TSV. Each contact C8 is in contact on the lower surface with the upper surface of one conductor L4.

Each conductor L5 is in contact on the lower surface with the upper surface of one contact C8. Each contact C9 is in contact on the lower surface with the upper surface of one conductor L5.

Each conductor L6 is in contact on the lower surface with the upper surface of one contact C9. Each contact C10 is in contact on the lower surface with the upper surface of one conductor L6.

A set of the transistor Tr2, the contacts CS2, CS5, C7, C8, C9, and C10, and the conductors L4, L5, and L6 realizes a circuit included in the second structure 200. Therefore, the second structure 200 has any shapes and arrangement of the transistors Tr2, the contacts CS2, CS5, C7, C8, C9, and C10, and the conductors L4, L5, and L6 realizing circuits included in the second structure 200.

The insulator 26 extends from the level of the upper surface of the substrate W2 to the level of the upper surfaces of the contacts C10. The insulator 26 fills a region where constituent elements are not arranged in a region from the level of the upper surface of the substrate W2 to the level of the upper surfaces of the contacts C10, that is, a region where the transistors Tr2, the contacts CS2, CS5, C7, C8, C9, and C10, and the conductors L4, L5, and L6 are not arranged.

Each joint terminal BP2U is in contact on the lower surface with the upper surface of one contact C10. The insulator 27 fills a region where the joint terminals BP2U are not located in a layer where the joint terminals BP2U are positioned.

The third structure 300 further includes contacts C11, C12, and C13, conductors L7, L8, 31, 33, 36, and 38, insulators 29, 34, 35, 37, 40, and 41, and memory pillars MP.

Each joint terminals BP3 is positioned in the lowermost layer of the third structure 300. The insulator 29 fills a region where the joint terminals BP3 are not located in the layer where the joint terminals BP3 are positioned.

Each contact C11 is in contact on the lower surface with the upper surface of one joint terminal BP3.

Each conductor L7 is in contact on the lower surface with the upper surface of one contact C11. Each contact C12 is in contact on the lower surface with the upper surface of one conductor L7.

Each conductor L8 is in contact on the lower surface with the upper surface of one contact C12.

The conductor 31 is positioned above the conductors L8. The conductor 31 has a plate-like shape along the XY plane. The conductor 31 functions as at least a part of a selection gate line SGDL. The lower surface of the conductor 31 is exposed and has a stepped terrace at ends.

The insulator 32 is positioned on the upper surface of the conductor 31. The insulator 32 has a plate-like shape along the XY plane.

The conductors 33 and the insulators 34 are stacked alternately one by one in the Z direction on the upper surface of the insulator 32 to constitute a stacked body. The conductors 33 and the insulators 34 each have a plate-like shape along the XY plane. Each conductor 33 functions as at least a part of a word line WL. FIG. 5 illustrates an example where n=8, that is, the number of memory cell transistors MT is eight. The conductors 33 function as at least a part of word lines WL0, WL1, WL2, WL3, WL4, WL5, WL6, and WL7 in this order from the lowermost one, respectively. The lower surface of each conductor 33 is exposed and has a stepped terrace at ends.

The insulator 35 is positioned on the upper surface of the uppermost conductor 33.

The conductor 36 is positioned on the upper surface of the insulator 35. The conductor 36 functions as at least a part of a selection gate line SGSL.

The insulator 37 is positioned on the upper surface of the conductor 36. The conductor 38 is positioned on the upper surface of the insulator 37. The lower surface of the conductor 38 is exposed and has a terrace at ends. The conductor 38 functions as, for example, a source layer.

The memory pillars MP extend along a Z-axis and penetrate through the stacked body including the conductors 31, 33, and 36 and the insulators 32, 34, 35, and 37. Each memory pillar MP includes an insulator CI, the semiconductor layer SM, and a memory film SS penetrating through the stacked body. The semiconductor layer SM covers the side surface of the insulator CI. The memory film SS covers the side surface of the semiconductor layer SM and is located between the semiconductor layer SM and the stacked body. The memory film SS is open at the upper end of the associated memory pillar MP. A part of the semiconductor layer SM is positioned in the opening and is in contact on the upper surface with the conductor 38.

It is also possible that an upper part of each of the memory pillars MP is positioned in the conductor 38, the memory film SS is open at a portion facing the conductor 38, and a part of the conductor 38 is positioned in the opening.

A portion facing the conductor 31 in each memory pillar MP functions as one selection gate transistor DT. A portion facing a conductor 33 in each memory pillar MP functions as one memory cell transistor MT. That is, each of the memory pillars MP constitutes a memory cell at an intersecting portion with one of the conductors 33. A portion facing the conductor 36 in each memory pillar MP functions as one selection gate transistor ST. The lower surface of the semiconductor layer SM is exposed on the lower surface of each memory pillar MP. The upper surface of the semiconductor layer SM is exposed on the upper surface of each memory pillar MP. As described above, the third structure 300 is constituted as an array chip including a memory cell array.

Each contact C13 is in contact on the lower surface with the upper surface of one conductor L8. Each of some contacts C13 is in contact on the upper surface with the lower surface of the semiconductor layer SM of one memory pillar MP. Each of some contacts C13 is in contact on the upper surface with the lower surface of one terrace portion of the conductors 31, 33, and 36.

The insulator 40 extends from the level of the upper surface of the insulator 29 to the level of the upper surface of the conductor 38. The insulator 40 fills a region where constituent elements are not arranged in the third structure 300, that is, a region where the contacts C11, C12, and C13, the conductors L7, L8, 31, 33, 36, and 38, the insulators 40, 32, 34, 35, and 37, and the memory pillars MP are not arranged.

The insulator 41 is positioned on the upper surfaces of the conductor 38 and the insulator 40.

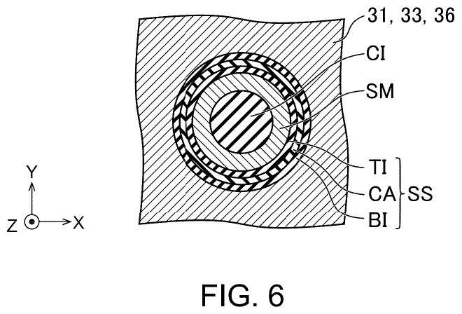

FIG. 6 is a sectional view illustrating a configuration example of a memory pillar of the storage device according to the first embodiment. FIG. 6 illustrates a cross-sectional structure of a memory pillar along the XY plane. In one example, the memory film SS includes a tunnel insulator TI, a charge accumulation film CA, and a block insulator BI.

The tunnel insulator TI surrounds the side surface of the semiconductor layer SM. The charge accumulation film CA surrounds the side surface of the tunnel insulator TI. The block insulator BI surrounds the side surface of the charge accumulation film CA. The conductor 31, 33, or 36 surrounds the side surface of the block insulator BI.

The semiconductor layer SM functions as channels (current paths) of the memory cell transistors MT and the selection gate transistors DT and ST. In one example, each of the tunnel insulator TI and the block insulator BI includes silicon oxide. The charge accumulation film CA accumulates charges therein. In one example, the charge accumulation film CA includes silicon nitride.

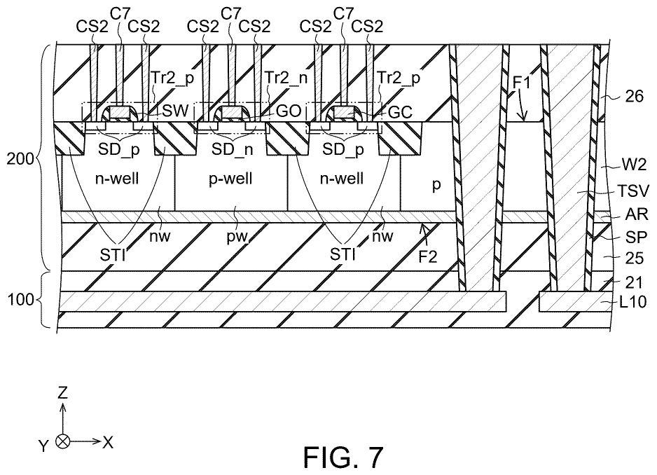

FIG. 7 is a sectional view illustrating a configuration example of a part of a first structure and a second structure according to the first embodiment. FIG. 7 illustrates a structure of the substrate W2 of the second structure 200 and a peripheral part thereof.

The second structure 200 further includes shallow trench isolation parts STI, n-well regions nw, p-well regions pw, and the impurity layer AR. The numbers of the p-well regions pw and the n-well regions nw are not limited to specific values.

The substrate W2 includes p-type impurities. Examples of the p-type impurities include boron (B).

Each of the n-well regions nw is positioned between adjacent two of the shallow trench isolation parts STI. The n-well regions nw spread from the upper surface of the substrate W2 to the lower surface thereof. The n-well regions nw include n-type impurities. Examples of the n-type impurities include phosphorus (P) and arsenic (As).

Each of the p-type well regions pw is positioned between adjacent two of the shallow trench isolation parts STI. The p-well regions pw spread from the upper surface of the substrate W2 to the lower surface thereof. The p-well regions pw include p-type impurities. In one example, the p-well regions pw include p-type impurities of a concentration equal to or higher than 1×10¹⁴ atoms/cm³ and equal to or lower than 2×10¹⁶ atoms/cm³ in a region including a boundary with the insulator 25. In one example, the concentration of the impurities is an average concentration.

Each of the shallow trench isolation parts sti is arranged between adjacent ones of a plurality of transistors Tr2_p and Tr2_n and extends in the-Z direction from the first surface F1 of the substrate W2 toward the second surface F2 thereof. The shallow trench isolation parts STI are constituted of an insulating material such as silicon oxide, as one example. Therefore, each of the shallow trench isolation parts STI electrically isolates portions near the first surface F1 of adjacent n-well region nw and p-well region pw from each other.

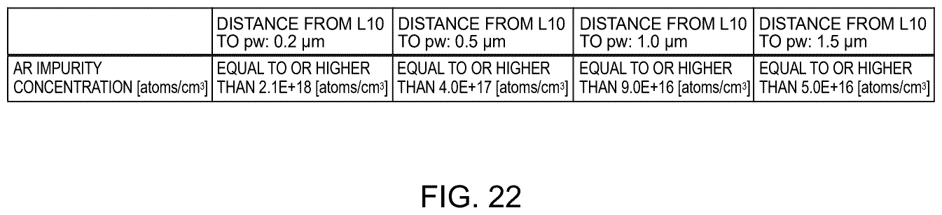

The impurity layer AR is arranged on bottom parts of the n-well regions nw and the p-well regions pw on the side of the second surface F2. The impurity layer AR may be arranged on the whole of the second surface F2 of the substrate W2. That is, the impurity layer AR is positioned between the substrate W2 and the insulator 25. The impurity layer AR is a p⁺-type impurity layer being higher in the p-type impurity concentration than the p-well regions pw. The impurity layer AR includes, for example, boron as impurities. While depending on the distance from the conductors L10 to the p-well regions pw (the film thickness of the insulators 21 and 25), an appropriate impurity concentration of the impurity layer AR has a relation as shown by a table of FIG. 22 and is preferably at least equal to or higher than 5.0×10¹⁶ atoms/cm³. A peak of the impurity concentration of the impurity layer AR is near the second surface F2 of the substrate W2. The impurity concentration of the impurity layer AR will be described later with reference to FIG. 22.

The impurity layer AR may include a certain amount of carbon. Carbon suppresses diffusion of the p-type impurities and can keep the thickness of the impurity layer AR thin and the impurity concentration high.

The impurity layer AR may be kept at the same voltage as that of The p-well regions pw. For example, the impurity layer ar may be set to a ground voltage. Alternatively, the impurity layer AR may be in an electrically floating state.

The transistors Tr2 include p-type transistors Tr2_p and n-type transistors Tr2_n. The transistors Tr2_p and Tr2_n are MOSFETs constituting the CMOS described above. The transistors Tr2_p and Tr2_n can be constituted of an LV (Low Voltage) transistor having a relatively low threshold voltage and a VLV (Very Low Voltage) transistor having a lower threshold voltage. In this case, the n-well regions nw and the p-well regions pw are formed to have relatively low impurity concentrations. Therefore, the p-well regions pw (or the n-well regions nw) are in a state of being easily inverted by a high voltage of the conductors L10. However, in the present embodiment, the impurity layer AR including a high concentration of p⁺-type impurities is arranged on the second surface F2 of the p-well regions pw. Therefore, the impurity layer AR can suppress inversion of the p-well regions pw even when the conductors L10 transmit a high voltage.

Each of the transistors Tr2_p is arranged in an active area between adjacent two of the shallow trench isolation parts STI. Each of the transistors Tr2_p is positioned in an n-well region nw and above the n-well region nw. Each of the transistors Tr2_p includes a gate insulator GO, a gate electrode GC, and a region (source/drain region) SD_p of one pair of a source and a drain. The gate insulator GO is positioned on the upper surface of the substrate W2. In one example, the gate insulator GO includes silicon oxide. The gate electrode GC is positioned on the upper surface of the gate insulator GO. In one example, the gate electrode GC includes polysilicon that has a conductive property due to implantation of impurities. The source/drain region SD_p sandwiches a portion of a region including the upper surface of the substrate W2 below the gate electrode GC. The source/drain region SD_p includes p-type impurities.

Each of the transistors Tr2_n is arranged in an active area between adjacent two of the shallow trench isolation parts STI. Each of the transistors Tr2_n is positioned in a p-well region pw and above the p-well region pw. Each of the transistors Tr2_n includes a gate insulator GO, a gate electrode GC, and a region (source/drain region) SD_n of one pair of a source and a drain. The source/drain region SD_n sandwiches a portion of a region including the upper surface of the substrate W2 below the gate electrode GC. The source/drain region SD_n includes n-type impurities.

Each of the contacts CS2, CS5, and C7, the shallow trench isolation parts STI, and the through-electrodes TSV has a tapered shape. Each of the constituent elements having a tapered shape has an area larger at the upper end than at the lower end, which decreases from the upper end to the lower end (in the −Z direction). That is, each of the contacts CS2, CS5, and C7, the shallow trench isolation parts STI, and the through-electrodes TSV has an area larger at an end on the side in the +Z direction than at an end on the side in the −Z direction.

A manufacturing method of the storage device 1 according to the first embodiment is described next.

A manufacturing process of the storage device 1 includes a process of individually manufacturing the first structure 100, the second structure 200, and the third structure 300, and a process of bonding the manufactured first, second, and third structures 100, 200, and 300 to each other. A manufacturing method of the second structure 200 according to the present embodiment is described below.

FIGS. 8 to 15 are sectional views illustrating one example of the manufacturing method of the second structure of the storage device according to the first embodiment.

As illustrated in FIG. 8, a thin insulator 25 (for example, silicon oxide) for protection is deposited on the second surface F2 of the substrate W2. The substrate W2 is, for example, a semiconductor substrate such as a silicon substrate. Next, a high concentration of p-type impurities (for example, boron) is implanted in the second surface F2 of the substrate W2 through the insulator 25 using an ion implantation method. Accordingly, the p⁺-type impurity layer AR is formed on the second surface F2 of the substrate W2. It is preferable that the impurity concentration of the impurity layer AR is at least equal to or higher than 5.0×10¹⁶ atoms/cm³.

In a case where carbon is also implanted in the impurity layer AR, first, carbon is implanted in the second surface F2 of the substrate W2 through the insulator 25 using the ion implantation method. It is preferable that the concentration of carbon is, for example, equal to or higher than 1.0×10¹⁹ atoms/cm³. Next, as described above, a high concentration of p-type impurities is implanted in the second surface F2 of the substrate W2 using the ion implantation method. Accordingly, diffusion of the p-type impurities is suppressed and the impurity layer AR that is thin in the film thickness and high in the concentration can be formed on the second surface F2.

Next, the material for the insulator 25 is further deposited on the insulator 25 on the second surface F2 of the substrate W2 as illustrated in FIG. 9.

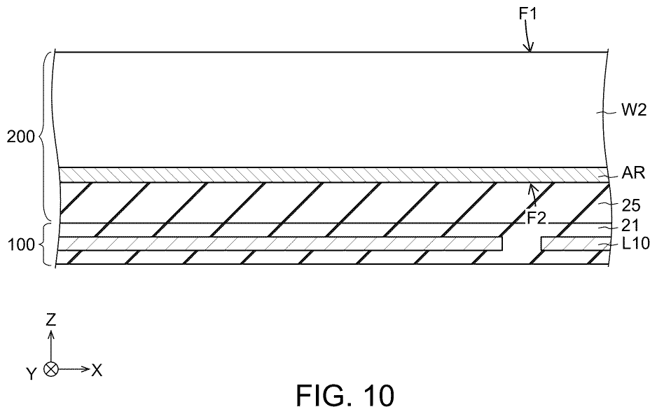

Next, the first structure 100 manufactured separately from the second structure 200 is bonded to the insulator 25 on the side of the second surface F2 of the second structure 200. FIG. 10 illustrates only an upper part of the first structure 100. The first structure 100 includes the conductors L10 arranged in the insulator 21. At this stage, a support substrate different from the first structure 100 may be bonded to the insulator 25 of the second structure 200. In this case, the support substrate is detached from the second structure 200 in a later process to bond the first structure 100 to the second structure 200 on the side of the second surface F2.

Next, the first surface F1 of the substrate W2 is polished using a CMP (Chemical Mechanical Polishing) method or the like to thin the substrate W2.

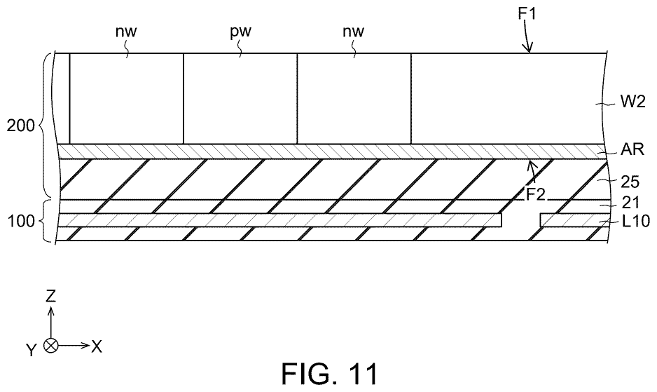

Next, the n-well regions nw and the p-well regions pw are formed in the substrate W2 using a lithography technique and the ion implantation technique as illustrated in FIG. 11. The n-well regions nw are formed, for example, by implanting n-type impurities such as phosphorus (P) or arsenic (As) from the first surface F1. The p-well regions pw are formed, for example, by implanting p-type impurities such as boron (B) from the first surface F1. The n-well regions nw and the p-well regions pw are formed adjacently to each other.

Either the n-well regions nw or the p-well regions pw can be formed first.

Next, a material for a hard mask 52 is deposited on the first surface F1 of the substrate W2. The material for the hard mask 52 in the formation region for the shallow trench isolation parts STI is selectively removed using a lithography technique and an etching technique.

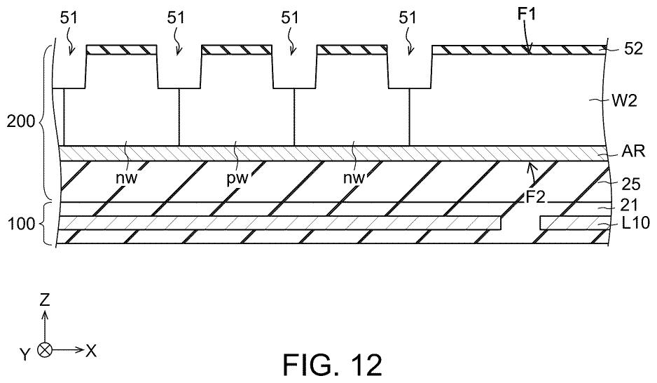

Next, the substrate W2 is etched from the first surface F1 toward the second substrate F2 by an etching technique such as an RIE (Reactive Ion Etching) method using the hard mask 52 as a mask. Accordingly, trenches 51 are formed in the formation region for the shallow trench isolation parts STI. That is, each of the trenches 51 is formed from the first surface F1 toward the second surface F2 in a boundary region between adjacent p-well region pw and n-well region nw as illustrated in FIG. 12. The side surface of each of the trenches 51 tapers in such a manner that the area of the trench 51 in the XY plane decreases in the-Z direction from the first surface F1 toward the second surface F2.

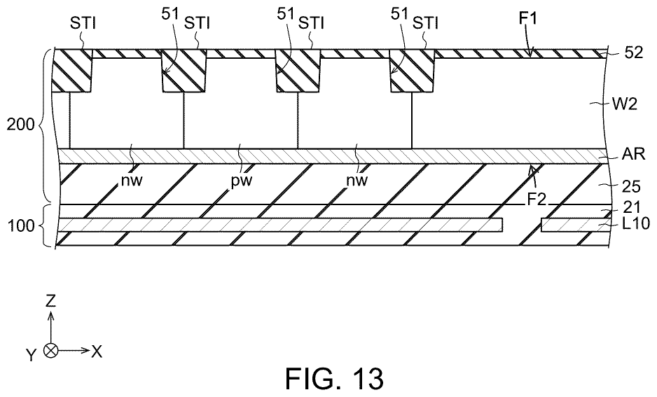

Next, an insulating material for the shallow trench isolation parts STI is deposited on the substrate W2 using a CVD (Chemical Vapor Deposition) method or the like, and is polished using the CMP method or the like. The shallow trench isolation parts STI are thereby formed in the trenches 51 as illustrated in FIG. 13.

Each of the shallow trench isolation parts STI has a shape along the shape of each of the trenches 51. That is, each of the shallow trench isolation parts STI extends in the −Z direction from the first surface F1 of the substrate W2 toward the second surface F2. The side surface of each of the shallow trench isolation parts STI tapers in such a manner that the area of the trench 51 in the XY plane decreases in the-Z direction from the first surface F1 toward the second surface F2.

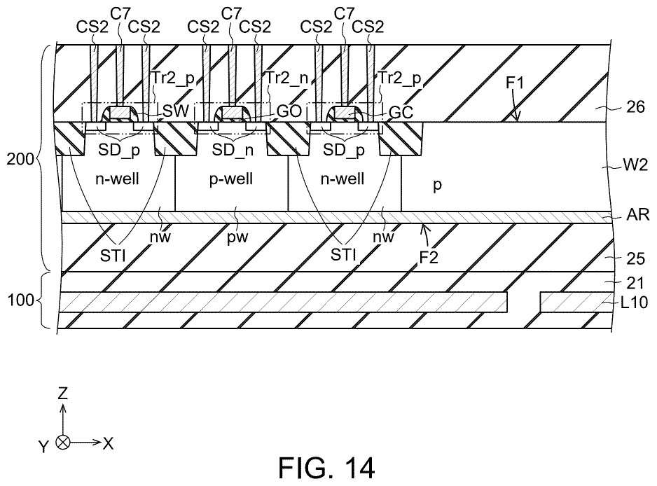

Next, after the hard mask 52 is removed, the gate insulators GO, the gate electrodes GC, sidewall insulating films SW, the insulator 26, and the contacts CS2 and C7 are formed as illustrated in FIG. 14.

For example, the gate insulators GO can be formed by a thermal oxidation method. The gate electrodes GC can be formed, for example, by depositing a material for the gate electrodes GC by the CVD method and subsequently processing the material using a photolithography process and anisotropic etching. The sidewall insulating films SW can be formed by depositing a material for the sidewall insulating films SW by the CVD method and subsequently anisotropically etching back the material.

Next, the source/drain regions SD_n and SD_p are formed on the substrate W2 by the ion implantation technique using the gate electrodes GC and the sidewall insulating films SW as a mask. The source/drain regions SD_n are formed, for example, by implanting n-type impurities such as phosphorus (P) or arsenic (As) in the p-well regions pw from the first surface F1. The source/drain regions SD_p are formed, for example, by implanting p-type impurities such as boron (B) in the n-well regions nw from the first surface F1.

Either the source/drain regions SD_n or SD_p can be formed first.

Next, the insulator 26 is deposited on a structure of the gate electrodes GC and the like.

Next, contact holes for the contacts CS2, and C7 are formed using a lithography technique and an etching technique. Next, a conductive material is filled in the contact holes, whereby the contacts CS2, and C7 are formed.

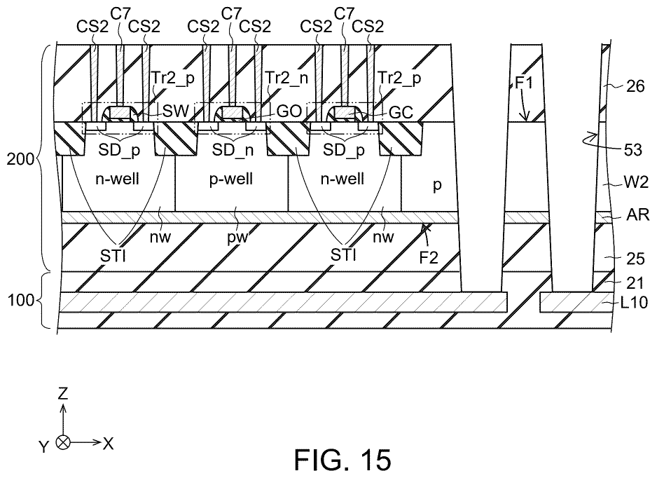

Next, trenches 53 illustrated in FIG. 15 are formed in the formation region for the through-electrodes TSV using a hard mask, a lithography technique, and an etching technique. Each of the trenches 53 penetrates through the insulator 26 and penetrates through the substrate W2 in the-Z direction from the first surface F1 to the second surface F2 to reach an associated conductor L10 of the first structure 100. The side surface of each of the trenches 53 tapers in such a manner that the area of the trench 53 in the XY plane decreases in the-Z direction from the first surface F1 toward the second surface F2.

Next, as illustrated in FIG. 7, the insulator (for example, a spacer film) SP is formed on the inner wall of each of the trenches 53. Next, the insulator SP at a bottom part of each of the trenches 53 is removed by etching back to expose the associated conductor L10 at the bottom part of the trench 53. Next, a material (for example, tungsten) for the through-electrodes TSV is formed in the inner side of each of the insulators SP for the trenches 53. Each of the through-electrodes TSV is thereby formed to be electrically connected to the associated conductor L10 in a state where the through-electrodes TSV are electrically separated from the substrate W2 as illustrated in FIG. 7.

Subsequently, the third structure 300 is bonded to the second structure 200 on the side of the first surface F1. In a case where the support substrate has been bonded to the second structure 200 on the side of the second surface F2, it suffices to detach the support substrate and then bond the first structure 100 on the side of the second surface F2.

By dicing the bonded first to third structures 100 to 300, the structures are singulated into semiconductor chips including the first to third structures 100 to 300. The storage device 1 according to the present embodiment is thereby completed.

According to the first embodiment, the p⁺-type impurity layer AR having a higher impurity concentration than the impurity concentration of the p-well regions pw in the second structure 200 is arranged at least at the bottom part of the p-well regions pw on the side of the second surface F2. The impurity layer AR is located on the whole surface of the second surface F2 of the substrate W2 and is positioned between the substrate W2 and the insulator 25. The impurity layer AR is electrically separated from the conductors L10 by the insulators 21 and 25. That is, the impurity layer AR is provided between the conductors L10 and the p-well regions pw in a state of being electrically separated from the conductors L10. Accordingly, formation of an inverted layer in the p-well regions can be suppressed even when a high voltage (for example, +30V) is applied to the conductors L10. As a result, a leak current between adjacent n-well regions nw can be suppressed.

Similarly, when the conductivity type of the impurities in the impurity layer AR is set to the n type, formation of an inverted layer in the n-well regions nw can be suppressed even when a negative voltage is applied to the conductors L10. As a result, a leak current between adjacent p-well regions pw can be suppressed.

For example, in a case where the first to third structures 100 to 300 are stacked as illustrated in FIG. 5, there is a case where a conductor L10 connected to the second structure 200 via a through-electrode TSV is arranged near the substrate W2 in the first structure 100. When a high voltage (for example, +30V) is applied to such a conductor L10, an inverted layer is formed on the second surface F2 of p-well regions pw in some cases. In the present embodiment, since the impurity layer AR is provided at the bottom part of each of the p-well regions pw, formation of such an inverted layer in the p-well regions pw can be suppressed. Accordingly, a leak current is unlikely to flow between adjacent n-well regions nw.

If the impurity layer AR is provided between each of the n-well regions nw and an adjacent p-well region pw, there is a concern about a decrease in a breakdown voltage between the semiconductor element in the n-well region nw and the p-well region pw or a breakdown voltage between the semiconductor element in the p-well region pw and the n-well region nw. Furthermore, a parasitic capacitance between the semiconductor elements in the n-well region nw and the p-well region pw and the impurity layer AR is increased.

In contrast thereto, according to the present embodiment, the impurity layer AR is arranged on the side of the second surface F2 of the substrate W2, and is the thickness of the substrate W2 away from the active area of the n-well regions nw and the p-well regions pw on the side of the first surface F1 where the semiconductor elements are formed. Therefore, the breakdown voltage between the semiconductor element in the n-well region nw and the p-well region pw, or the breakdown voltage between the semiconductor element in the p-well region pw and the n-well region nw is unlikely to decrease. Furthermore, the parasitic capacitance between the semiconductor elements in the n-well regions nw and the p-well regions pw and the impurity layer AR is unlikely to increase. Therefore, the storage device 1 according to the present embodiment operates stably and the reliability can be enhanced.

### Second Embodiment

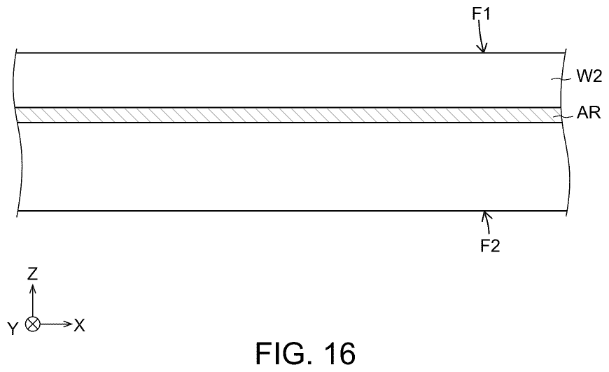

FIGS. 16 to 18 are sectional views illustrating one example of a manufacturing method of a second structure of a storage device according to a second embodiment. In the second embodiment, the impurity layer AR of the second structure 200 is formed from the side of the first surface F1 of the substrate W2.

For example, a high concentration of p-type impurities (for example, boron) is implanted in the first surface F1 of the substrate W2 using the ion implantation method as illustrated in FIG. 16. The p⁺-type impurity layer AR is thereby formed in the substrate W2. The position of the impurity layer AR in the Z direction is set to cause the thickness of the substrate W2 from the first surface F1 to the impurity layer AR to be a thickness necessary for the p-well regions pw, the n-well regions nw, and the semiconductor elements. The impurity concentration of the impurity layer AR is, for example, equal to or higher than 2×10¹⁷ atoms/cm³ as in the first embodiment. More preferably, the impurity concentration of the impurity layer AR is, for example, equal to or higher than 5×10¹⁷ atoms/cm³.

In a case where carbon is also implanted in the impurity layer AR, first, carbon is implanted in the formation position for the impurity layer AR from the first surface F1 of the substrate W2 using the ion implantation method. Next, a high concentration of p-type impurities is implanted from the first surface F1 of the substrate W2 using the ion implantation method as described above. This suppresses diffusion of the p-type impurities and enables the impurity layer AR that is thin in the film thickness and high in the concentration to be formed in the substrate W2.

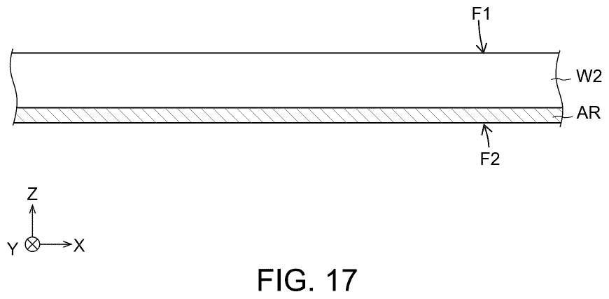

Next, the substrate W2 is polished from the second surface F2 using the CMP Method or the like to expose the impurity layer ar as illustrated in FIG. 17.

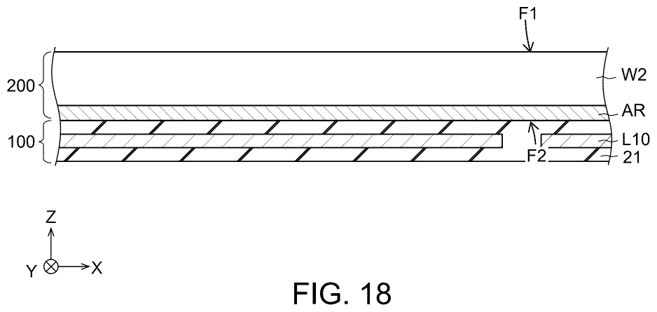

Next, the first structure 100 manufactured separately from the second structure 200 is bonded to the impurity layer AR on the side of the second surface F2 of the second structure 200. FIG. 18 illustrates only an upper part of the first structure 100. The first structure 100 includes the conductors L10 arranged in the insulator 21. It is also possible that the insulator 25 is deposited on the impurity layer AR on the side of the second surface F2 of the substrate W2 and that the first structure 100 is bonded to the insulator 25.

Subsequent processes in the second embodiment can be the same as those described with reference to FIGS. 11 to 15 in the first embodiment. Accordingly, the second embodiment can manufacture a configuration identical to that of the first embodiment.

It is alternatively possible that, after the first structure 100 is bonded to the second surface F2 of the substrate W2, the first surface F1 of the substrate W2 is polished by the CMP method to adjust the thickness of the substrate W2, and that impurities are implanted from the first surface F1 of the substrate W2 to form the impurity layer AR on the side of the second surface F2 of the substrate W2. Also in this case, subsequent processes can be the same as those described with reference to FIGS. 11 to 15 in the first embodiment.

### Third Embodiment

One example of a manufacturing method of a second structure of a storage device according to a third embodiment is described. In the third embodiment, after the process described with reference to FIG. 16 is performed and before the first structure 100 is bonded to the substrate W2, the p-well regions pw, the n-well regions nw, and the semiconductor elements are formed on the side of the first surface F1 of the substrate W2 through the processes described with reference to FIGS. 11 to 15 and 7.

Next, the substrate W2 is polished from the second surface F2 using the CMP method or the like to expose the impurity layer AR, and the first structure 100 is bonded to the impurity layer AR on the side of the second surface F2 of the second structure 200. It is also possible that the insulator 25 is deposited on the impurity layer AR on the side of the second surface F2 of the substrate W2 and that the first structure 100 is bonded to the insulator 25.

The configuration identical to that of the first embodiment can also be manufactured by the manufacturing method according to the third embodiment.

### Fourth Embodiment

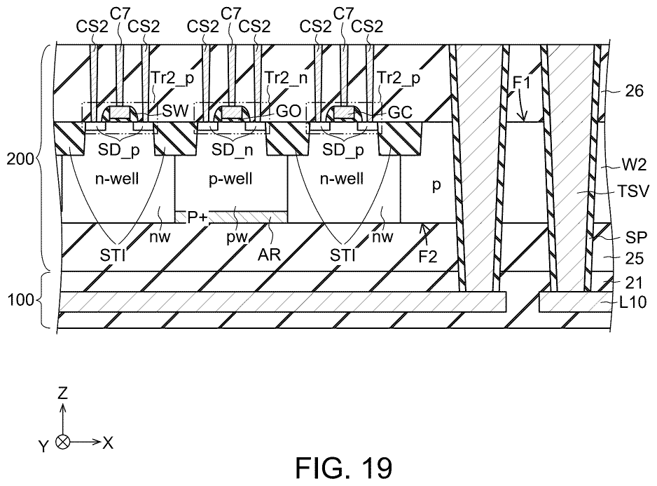

FIG. 19 is a sectional view illustrating a configuration example of a second structure of a storage device according to a fourth embodiment. In the fourth embodiment, the impurity layer AR is provided for a portion corresponding to each of the p-well regions pw in the second surface F2 of the substrate W2, and is not provided for the n-well regions nw.

In a case where the conductors L10 transmit a high voltage (for example, +30V) to be applied to the word lines WL, it suffices to suppress formation of an inverted layer in the p-well regions pw. In this case, an inverted layer is not formed in the n-well regions nw.

Therefore, it suffices that a p⁺-type impurity layer AR having a higher impurity concentration than that of the p-well regions pw in the second structure 200 is provided at least at a bottom part of each of the p-well regions pw on the side of the second surface F2. In the fourth embodiment, the impurity layer AR is provided only for the p-well regions pw on the second surface F2 of the substrate W2. Also with this configuration, a leak current between adjacent n-well regions nw can be suppressed.

The impurity layer AR according to the fourth embodiment can be obtained by adding a lithography process to the formation process of the impurity layer AR that has been described with reference to FIG. 8 to selectively implant p-type impurities (for example, boron) in the formation region for the p-well regions pw. To suppress diffusion of the p-type impurities, carbon may be additionally implanted. The rest of the manufacturing process of the fourth embodiment can be the same as that of the first embodiment. the second structure 200 according to the fourth embodiment can be thereby formed. The second structure 200 according to the fourth embodiment can also be formed by application of the second or third embodiment.

### Fifth Embodiment

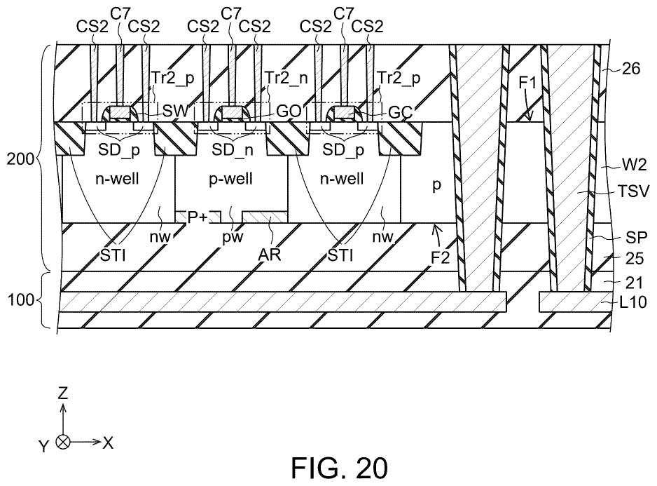

FIG. 20 is a sectional view illustrating a configuration example of a second structure of a storage device according to a fifth embodiment. In the fifth embodiment, the impurity layer AR is arranged partially in the p-well regions pw on the second surface F2 of the substrate W2. Similarly in the fourth embodiment, the impurity layer AR is not arranged for the n-well regions nw.

The impurity layer AR is arranged partially in the p-well regions pw on the second surface F2 of the substrate W2. In this case, an inverted layer may be formed in p-well regions pw where the impurity layer AR is not arranged on the second surface F2. However, since an inverted layer is not formed in portions where the impurity layer AR is arranged, an inverted layer formed in the p-well regions pw does not electrically connect adjacent n-well regions nw to each other. Therefore, a leak current is unlikely to flow between adjacent n-well regions nw.

Also the impurity layer AR according to the fifth embodiment can be obtained by adding a lithography process to the formation process of the impurity layer AR that has been described with reference to FIG. 8 to selectively implant p-type impurities (for example, boron) in the formation region for the p-well regions pw. To suppress diffusion of the p-type impurities, carbon may be additionally implanted. The rest of the manufacturing process of the fifth embodiment can be the same as that of the first embodiment. The second structure 200 according to the fifth embodiment can be thereby formed. The second structure 200 according to the fifth embodiment can also be formed by application of the second or third embodiment.

### Sixth Embodiment

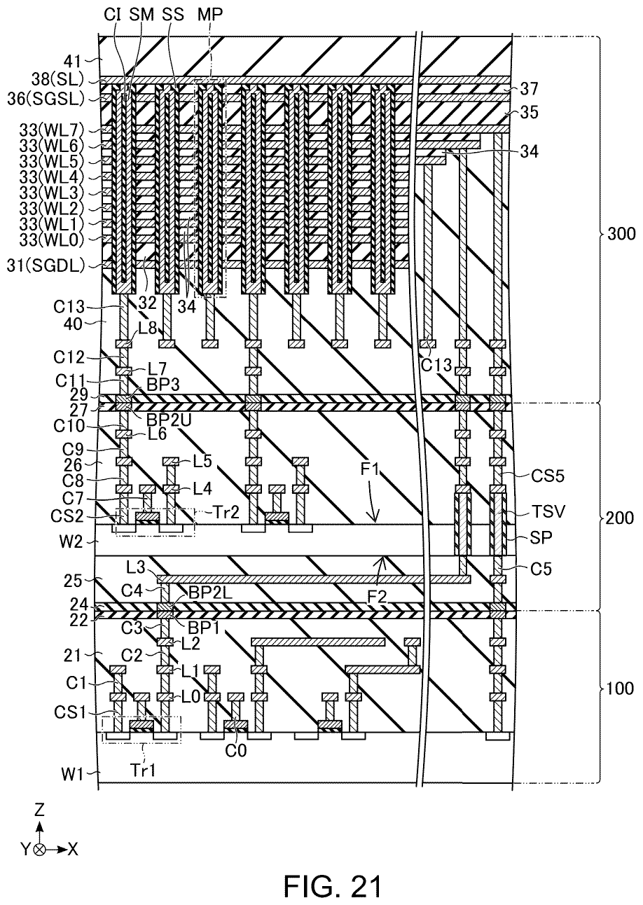

FIG. 21 is a sectional view illustrating a configuration example of a storage device according to a sixth embodiment. In the sixth embodiment, instead of the conductors L10, conductors L3 that face p-well regions pw and that transmit a positive high voltage are positioned in the second structure 200.

The first structure 100 does not include the conductors L10 and the contacts C15. Meanwhile, the second structure 200 includes the conductors L3 and contacts C4 and C5.

Each of the contacts C4 is in contact on the lower surface with the upper surface of one joint terminal BP2L.

Each joint terminal BP2L is positioned in the lowermost layer of the second structure 200. The insulator 24 fills a region where the joint terminals BP2L are not located in the layer where the joint terminals BP2L are positioned.

Each conductor L3 is in contact on the lower surface with the upper surface of one contact C4. In one example, each of the conductors L3 includes copper (Cu), aluminum (Al), and (or) tungsten (W). Each contact C5 is in contact on the lower surface with the upper surface of one conductor L3. The conductors L3 are electrically connected to the voltage generation circuit 14 to receive a high positive voltage. The conductors L3 are arranged on the side of the second surface F2 of the substrate W2 with the insulator 25 interposed therebetween. Each of the conductors L3 is electrically connected to a transistor Tr1 in the first structure 100 via the contact C4 and the like. The conductors L3 are located between the first structure 100 and the second structure 200 and are electrically insulated from the substrate W2 by the insulator 25. Each of the conductors L3 is electrically connected to conductors 31, 33, or 36 of the third structure 300 via a through-electrode TSV and the like.

Each of the joint terminals BP1 of the first structure 100 is in contact on the lower surface with the upper surface of one contact C3. The insulator 22 fills a region where the joint terminals BP1 are not located in a layer where the joint terminals BP1 are positioned. Each of the joint terminals BP1 is electrically connected to an associated one of the joint terminals BP2L.

The rest of the configuration of the sixth embodiment can be the same as that of the first embodiment. Accordingly, the sixth embodiment can obtain effects identical to those of the first embodiment. (Impurity concentration of impurity layer AR)

FIG. 22 is a table showing a relation between the impurity concentration of the impurity layer AR where an inverted layer is not formed and the distance from each of the conductors L10 or L3 to an associated one of the p-well regions pw. In this simulation, the distance between the impurity layer AR and each conductor L10 or L3 was set to 0.2 μm, 0.5 μm, 1.0 μm, and 1.5 μm and the voltage to be applied to the conductors L10 or L3 was set to +33V. The distance between the impurity layer AR and each conductor L10 or L3 is the thickness of the insulators (for example, silicon dioxide films) 21 and 25 between the conductor L10 or L3 and the associated p-well region pw. An inverted layer is considered to have been formed when the density of holes has become higher than that of electrons in an interface of the second surface F2 of the p-well regions pw.

As a result, as shown by FIG. 22, in the case where the distance between the impurity layer AR and each conductor L10 or L3 was 0.2 μm, an inverted layer was not formed in the impurity layer AR or the p-well regions pw when the p-type impurity concentration of the impurity layer AR was equal to or higher than 2.1×10¹⁸ atoms/cm³. In the case where the distance between the impurity layer AR and each conductor L10 or L3 was 0.5 μm, an inverted layer was not formed in the impurity layer AR or the p-well regions pw when the p-type impurity concentration of the impurity layer AR was 4.0×10¹⁷ atoms/cm³. In the case where the distance between the impurity layer AR and each conductor L10 or L3 was 1.0 μm, an inverted layer was not formed in the impurity layer AR or the p-well regions pw when the p-type impurity concentration of the impurity layer AR was equal to or higher than 9.0×10¹⁶ atoms/cm³. In the case where the distance between the impurity layer AR and each conductor L10 or L3 was 1.5 μm, an inverted layer was not formed in the impurity layer AR or the p-well regions pw when the p-type impurity concentration of the impurity layer AR was 5.0×10¹⁶ atoms/cm³.

Since the distance between the impurity layer AR and each conductor L10 or L3 is normally 1.5 μm or shorter, it is preferable that the p-type impurity concentration of the impurity layer AR is at least equal to or higher than 5.0×10¹⁶ Atoms/cm³.

The foregoing descriptions are based on the examples in which the semiconductor device of the embodiments described above is a storage device. The embodiments described above are applicable to structures that are bonded to each other and that include the transistors Tr2 and the conductors L10 (or L3) as the first structure 100 and the second structure 200. Examples of such other semiconductor devices include an image sensor and ICs (Integrated Circuits). In this case, the third structure 300 is not provided. Alternatively, the third structure 300 has semiconductor elements other than a memory cell array.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a first structure having a plurality of first semiconductor elements arranged therein;
a second structure stacked on the first structure, and comprising a substrate comprising a first surface and a second surface on an opposite side to the first surface, a first well region of a first conductivity type arranged on a side of the first surface of the substrate, a second well region of a second conductivity type arranged on the side of the first surface of the substrate to be adjacent to the first well region, and a first impurity layer of the first conductivity type arranged at least on a side of the second surface of the first well region and having a higher impurity concentration than that of the first well region; and
a first conductor located between the first structure and the second structure and electrically separated from the substrate.

2. The device of claim 1, the first impurity layer is located on a whole of the second surface of the substrate.

3. The device of claim 1, wherein the first impurity layer is arranged for the first well region in the second surface of the substrate, and is not arranged for the second well region.

4. The device of claim 1, wherein the first impurity layer is arranged partially for the first well region in the second surface of the substrate.

5. The device of claim 1, wherein a peak of an impurity concentration of the first impurity layer is near the second surface of the substrate.

6. The device of claim 1, wherein impurities comprised in the first impurity layer are boron.

7. The device of claim 1, wherein an impurity concentration of the first impurity layer is equal to or higher than 5×10¹⁶ atoms/cm³.

8. The device of claim 6, wherein the first impurity layer comprises carbon.

9. The device of claim 1, further comprising a first insulator located between the first impurity layer and the first conductor.

10. The device of claim 6, wherein the first impurity layer is kept at a same voltage as that of the first well region or a ground voltage.

11. The device of claim 1, further comprising a shallow trench isolation part located between the first well region and the second well region, and arranged in the substrate from the first surface toward the second surface.

12. The device of claim 1, wherein the first structure is bonded to the second structure on a side of the second surface.

13. The device of claim 1, further comprising a third structure stacked on the second structure on a side of the first surface and comprising a memory cell array.

14. The device of claim 13, further comprising a through-electrode penetrating through the substrate, electrically separated from the substrate, and electrically connecting the memory cell array and the first conductor to each other.

15. The device of claim 13, wherein
the memory cell array comprises
a stacked body comprising a plurality of second conductors and a plurality of second insulators stacked alternately one by one, and
a plurality of columnar bodies each comprising a semiconductor layer penetrating through the stacked body and a memory layer located between the stacked body and the semiconductor layer, and constituting memory cells at intersecting positions with the second conductors, and
the first structure comprises a plurality of first transistors each electrically connected to any of the second conductors.

16. The device of claim 15, wherein the first transistors constitute a drive circuit configured to control a voltage to be applied to any of the second conductors.

17. The device of claim 15, wherein the second structure comprises a plurality of second transistors each electrically connected to the semiconductor layer of any of the columnar bodies.

18. The device of claim 17, wherein the second transistors constitute a detection circuit configured to detect data stored in the memory cells.

19. A manufacturing method of a semiconductor device, the method comprising:
implanting impurities of a first conductivity type in a second surface of a substrate comprising a first surface and the second surface on an opposite side to the first surface to form a first impurity layer;
forming a first well region of a first conductivity type and a second well region of a second conductivity type in the substrate on a side of the first surface; and
forming semiconductor elements in the first and second well regions, wherein
the first impurity layer is located at least on a side of the second surface of the first well region and has a higher impurity concentration than that of the first well region.

20. The method of claim 19, further comprising
after forming the first impurity layer,
forming a first insulator on the first impurity layer, and
bonding a first structure comprising a first conductor to the first insulator on a side of the second surface of the substrate to cause the first conductor to face at least the first well region.
